(19) United States
(12) Patent Application Publication
(10) Pub. No.: US 2013/0030742 A1
(43) Pub. Date: Jan. 31, 2013

(54) METHOD AND SYSTEM FOR MONITORING A SYNCHRONOUS MACHINE

(71) Applicants: Arijit Banerjee, Cambridge, MA (US); Somakumar Ramachandrapanicker, Bangalore (IN); Haiyan Sun, Schenectady, NY (US); Subhra Samanta, Bangalore (IN); Srinivas Satya Sai Mallampalli, Bangalore (IN)

(72) Inventors: Arijit Banerjee, Cambridge, MA (US); Somakumar Ramachandrapanicker, Bangalore (IN); Haiyan Sun, Schenectady, NY (US); Subhra Samanta, Bangalore (IN); Srinivas Satya Sai Mallampalli, Bangalore (IN)

(21) Appl. No.: 13/558,890

(22) Filed: Jul. 26, 2012

(30) Foreign Application Priority Data
Jul. 28, 2011 (IN) 2585/CHE/2011

(51) Int. Cl. G01R 23/02; G01R 23/14; G06F 19/00

(52) U.S. Cl. 702/76; 324/76.39; 324/76.41

(57) ABSTRACT

A method for monitoring a synchronous machine is described. The method includes injecting a narrowband sinusoidal signal at a first end of a field winding of the synchronous machine. The method further includes monitoring a voltage at a second end of the field winding with respect to ground. The method then identifies a resonant frequency based on the monitored voltage, and generates a winding health indicator based on the identified resonant frequency and an expected resonant frequency.

### BACKGROUND

Embodiments presented herein relate generally to electrical machines and more particularly to monitoring synchronous machines.

A synchronous machine is an AC electrical machine that operates at a speed synchronous with the power supply frequency. Synchronous machines include a stator that carries the armature winding, a rotor that carries the field winding, and a brush-slip ring assembly for exciting the field windings on the rotor. The field windings are excited by a DC supply voltage. The DC supply voltage may be provided from an external source (separately excited synchronous machines), or provided by a generator mounted on the rotor (self-excited synchronous machines). The field windings are typically insulated using, for example, insulating varnish.

During operation of the synchronous machine, the field insulation may degrade, due to various factors, such as, heat dissipation of the field winding, internal heating of the synchronous machine, partial discharge phenomena, dust, water (humidity, condensation, and unwanted submergence), mechanical forces, electrical disturbances, and so forth. Such degradation of the field insulation may cause short-circuits within the field windings, and short-circuits with ground. The winding insulation degradation eventually leads to complete breakdown of the winding insulation, and may result in catastrophic failure of the synchronous machine. To prevent such failure, early warning systems exist, that monitor winding failure degradation.

One such system relies on injecting a low frequency square wave signal into the field winding and identifying winding failure based on a measured response. However, such systems are typically restricted by a maximum resistance that can be measured for predicting failure. Further, systems such as meggers are available, that can measure insulation resistances to a higher range. However, typically such systems require the synchronous machine to be taken off line for testing. Such down-time may result in unwanted service outage and loss of revenue.

### BRIEF DESCRIPTION OF THE INVENTION

A method for monitoring a synchronous machine is described. The method includes injecting a narrow band sinusoidal signal at a first end of a field winding of the synchronous machine. The method further includes monitoring a voltage at a second end of the field winding with respect to ground. The method then identifies a resonant frequency based on the monitored voltage, and generates a winding health indicator based on the identified resonant frequency and an expected/baseline resonant frequency or resonant frequency measured under healthy condition.

A system for monitoring a synchronous machine is described. The system includes a signal generator for injecting a narrowband sinusoidal signal at a first end of the field winding of the synchronous machine. The system further includes a monitoring module for monitoring at a second end of the field winding, a voltage with respect to ground. The system also includes a spectrum analyzer for identifying a resonant frequency based on the monitored voltage. Finally, the system includes a prognostic module for generating a winding health indicator based, at least in part, on the identified resonant frequency.

In one embodiment, the monitoring module is configured to monitor the winding to ground current due to the injected narrowband sinusoidal signal. The spectrum analyzer then processes the winding to ground current to prognosticate winding health. The spectrum analyzer may identify a resonant frequency, and a frequency corresponding to zero phase difference between the winding to ground current and the applied voltage. The prognostic module may then generate a winding health indicator based on the difference between the two frequencies.

A computer program product comprising a non-transitory computer readable medium encoded with computer-executable instructions is described. The computer-executable instructions, when executed, cause one or more processors to inject a narrowband sinusoidal signal at a first end of a field winding of the synchronous machine, monitor a voltage at a second end of the field winding with respect to ground, identify a resonant frequency based on the monitored voltage, and generate a winding health indicator based on the identified resonant frequency and an expected resonant frequency.

### BRIEF DESCRIPTION OF THE DRAWINGS

FIG. 1 illustrates an example environment in which a synchronous machine monitoring system may operate, according to one embodiment;

FIG. 2 illustrates an example synchronous machine monitoring system, according to one embodiment; and

FIG. 3 is a flowchart of an example method for monitoring a synchronous machine, according to one embodiment.

### DETAILED DESCRIPTION OF THE INVENTION

Embodiments presented herein describe techniques for monitoring health of synchronous machines. The techniques include monitoring field windings of synchronous machines by probing the field winding with a narrowband sinusoidal signal, such as a sinusoidal chirp, and monitoring spectral characteristics of the field winding, such as resonance frequency condition and phase conditions, to determine the health of the field winding. In one embodiment, the monitored spectral characteristics may be compared to an expected, baseline, or healthy state spectral characteristics. For the purpose of this disclosure, the expected characteristic, baseline characteristic, and the health state characteristic may be used interchangeably. In various embodiments, the techniques described herein detect field winding insulation faults, such as field-ground faults, and inter winding faults. The health monitoring of the synchronous machines, according to the embodiments presented herein, do not require the synchronous machine to be taken off-line. In other words, the health monitoring techniques described herein enable monitoring of online synchronous machines. Although the following description describes health monitoring for synchronous generators or alternators, the embodiments presented herein apply equally to other electrical machines as well.

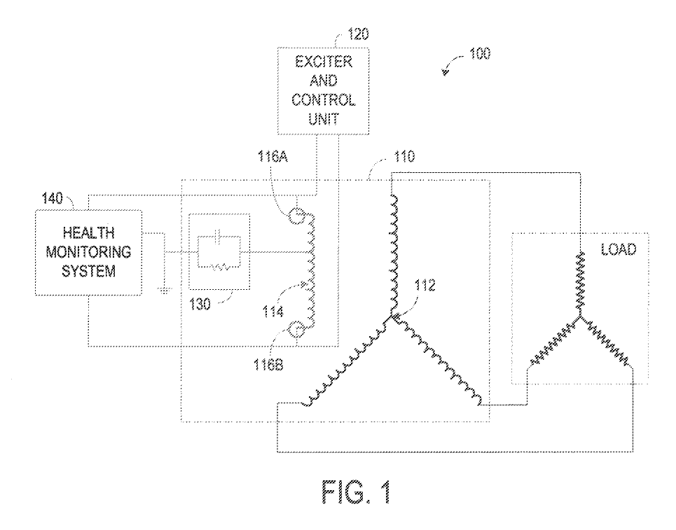

FIG. 1 illustrates an example environment 100 in which a synchronous machine monitoring system may operate, according to one embodiment. The environment 100 includes a synchronous machine 110, an exciter and control unit 120, and a health monitoring system 140. The synchronous machine 110 may be connected to a load. Although FIG. 1 illustrates an electrical load connected to the synchronous machine 110, it should be appreciated that in implementations where the synchronous machine 110 is a synchronous motor, the load may be a mechanical load.

The synchronous machine 110 is an electromechanical energy conversion device where the rotor rotates at the same speed as the rotational speed of a rotating magnetic field. Example synchronous machines include synchronous generators, synchronous motors, and power factor compensators. The synchronous machine 110 may be switched between a motoring mode and a generating mode by changing the electrical connections. For instance, in mobile combustion engines, the synchronous machine 110 may be an integrated starter-generator. The synchronous machine 110 operates in the motoring mode, accepting electrical energy from an onboard battery to start the combustion engine. Once the combustion engine is fired up, control electronics switch the synchronous machine 110 to the generating mode, accepting mechanical energy from the combustion engine shaft, and generating electrical power. The synchronous machine 110 includes an armature winding 112 and a field winding 114. Typically, in low power and low torque applications the synchronous machine 110 may be of a rotating armature type including the armature winding 112 disposed on the rotor, and the field winding 114 disposed on the stator. In industrial applications involving high torque and high power, the synchronous machine 110 may be of a rotating field type including the armature winding 112 disposed on the stator, and the field winding 114 disposed on the rotor. The field winding 114 is connected to the exciter and control unit 120 via field terminals 116A and 116B.

The exciter and control unit 120 includes an exciter such as, but not limited to, a DC generator, a battery, a rectified AC supply, or a static exciter, to excite the field windings 114. A static exciter feeds back a portion of the AC from each phase of generator output to the field windings 114, as DC excitations, through a system of transformers, rectifiers, and reactors. An external DC source may be used for initial excitation of the field windings. The exciter applies an excitation voltage, herein referred to as field voltage to the field windings 114 of the synchronous machine 110, thereby causing a field current to flow through the field winding 114. Due to rotation of the field windings 114, the flux linked to stationary coils, disposed in a stator of the synchronous machine 110, varies in a sinusoidal fashion, causing a sinusoidal variation of voltage across the terminals of the stationary coils. The exciter and control unit 120 controls the operation of the synchronous machine 110. For example, the exciter and control unit 120 may control the field voltage and field current supplied to the field windings 114, so that the voltage at the output remains constant. Further, the exciter and control unit 120 may control the power delivered to the synchronous machine 110 or the power delivered from the synchronous machine 110. The exciter and control unit 120 may also control the power factor of the synchronous machine 110.

Prolonged use of the synchronous machine 110 may degrade lamination of the field winding 114 and may cause inter-turn faults, and ground faults. FIG. 1 illustrates an equivalent circuit for a ground fault 130. A ground fault is one where the lamination of the field winding 114 has degraded, thus causing a short circuit between the field winding 114 and the ground. Typically, the housing of the synchronous machine 110 is connected to ground for safety from electrical shocks. When the lamination of the field winding 114 degrades, a short circuit may result between the field winding 114 and the housing of the synchronous machine 110, thus causing the ground fault 130. The ground fault 130 may be modeled as a parallel connection of a resistance (representing a resistive component of the ground fault 130) and a capacitance (representing a capacitive component of the ground fault 130). The resistive component represents insulation resistance between the field winding 114 and ground. While, the capacitive component represents the dielectric strength of the field winding insulation. The ground fault 130 forms a tank circuit together with the inductive component of the field winding 114 between the field terminals 116A/116/B and the location of ground fault 130 in the field winding 114. In order to monitor the health of the insulation one may monitor the resistive and capacitive components or a parameter dependent on the components. For example, the resistive component will be very high in case of a healthy insulation, while as it ages, the insulation resistance decreases. In one embodiment, the health of the insulation is monitored through measurement of quantities that reflects these parameters, such as, but not limited to field to ground current and field to ground voltage.

Various embodiments presented herein may be applied to detect the ground fault 130 in the field winding. Embodiments presented herein are described for the rotating field type synchronous machine. However, it should be appreciated that the embodiments may apply equally to all types of synchronous machines.

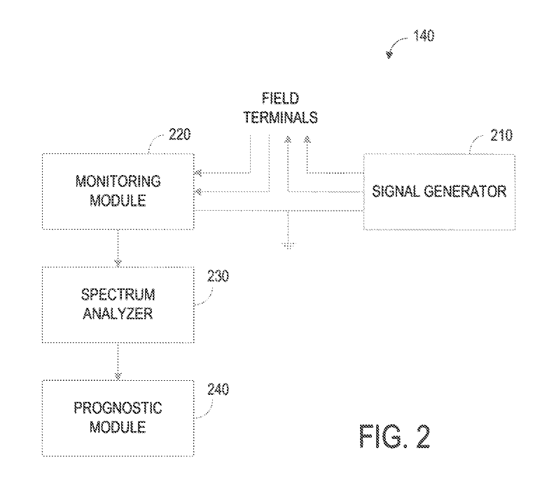

The ground fault 130 may be detected by the monitoring system 140. The monitoring system 140 monitors the health of the synchronous machine using frequency injection and signal monitoring. The monitoring system 140 is connected to the field winding 114 via the field terminals 116A and 116B. Referring now to FIG. 2, an example synchronous machine monitoring system is illustrated, according to one embodiment. The monitoring system 140 includes a signal generator 210, a monitoring module 220, a spectrum analyzer 230, and a prognostic module 240.

The signal generator 210 generates a narrowband sinusoidal signal for injecting into the field winding 114. The signal generator 210 may generate a narrowband sinusoidal chirp, or frequency sweep signal for injection. The injection sinusoidal signal may be defined in the signal generator 210 as a start frequency and an end frequency. Alternatively, the injection sinusoidal signal may be defined using a center frequency and bandwidth of the narrowband sinusoidal signal. It should be appreciated that both definitions refer to the range of injected frequencies, and will be referred to herein as the “frequency band”.

The frequency band may be decided based on a healthy state resonance frequency of the field winding 114 of the healthy synchronous machine 110. Typically, synchronous machines having the same build specifications have the same resonance frequency of the field winding 114, immediately after manufacture, with minor variations. The healthy state resonance frequency of the field winding of the synchronous machine 110 of each build specification may be identified by, for example, a broadband sweep frequency response analysis or a simulation, and stored in a memory associated with the signal generator 210. The signal generator 210 may then detect the model of the synchronous machine, and select the appropriate frequency band from the memory. In another implementation, the signal generator 210 may be programmed to operate in a learning mode that performs a broadband sweep frequency response analysis only upon first installation, and identify the healthy state resonance frequency of the synchronous machine 110. Once the healthy state resonance frequency is identified, the signal generator 210 may only operate in a protection mode, and inject a narrowband sinusoidal signal within the frequency band.

The signal generator 210 may inject the narrowband sinusoidal signal continuously in the protection mode. Alternatively, the signal generator 210 may inject the narrowband sinusoidal signal intermittently, after fixed intervals of time.

The signal generator 210 may inject the narrowband sinusoidal signal at one or both of the field terminals 116A and 116B. For example, in a fault detection mode, to detect presence of a ground fault 130 or an impending ground fault, the signal generator 210 may inject the narrowband sinusoidal signal at only one field terminal 116A or 116B. In a fault location mode, the signal generator 210 may inject the narrowband sinusoidal signal at both field terminals 116A and 116B, to locate the position of the ground fault 130 within the field winding 114.

In the fault detection mode, the monitoring module 220 measures the field voltage at the opposite field terminal 116A or 116B, with respect to ground, referred to herein as “field to ground voltage”. For instance, if the signal generator 210 injects the narrowband sinusoidal signal at field terminal 116A, the monitoring module 220 measures the field to ground voltage at field terminal 116B, and vice versa. In the fault location mode, the signal generator 210 may intermittently inject the narrowband sinusoidal signal at both field terminals 116A and 116B in synchronization, such that while the narrow band sinusoidal signal is injected at field terminal 116A, the monitoring module 220 measures the field to ground voltage at field terminal 116B, and when the narrowband sinusoidal signal is injected at field terminal 116B, the monitoring module 220 measures the field to ground voltage at field terminal 116A.

Once the ground fault 130 has been detected, the health monitoring system 140 may switch to the fault location mode. The fault may be located in any section of the field winding. The signal generator 210 first injects the narrowband sinusoidal signal at the field terminal 116A. The monitoring module 220 measures the field to ground voltage and the field to ground current at field terminal 116B. The spectrum analyzer 230 then identifies the resonant frequency of the field windings 114. The spectrum analyzer 230 then computes a first value of insulation impedance at the identified resonant frequency. In an identical manner, the process is repeated for the opposite side of the field windings 114. In other words, the signal generator 210 injects the narrowband sinusoidal signal at field terminal 116B, and the monitoring module 220 measures the field to ground voltage and field to ground current at field terminal 116A. The spectrum analyzer 230 then computes a second value of insulation impedance at the identified resonance frequency. Since only the real component of the winding impedance remains at resonance, knowing the value of the field winding resistance, the difference between the insulation impedances at the identified resonant frequency yields information as to the location of the ground fault 130. The location of the ground fault 130 is indicated as in terms of the percentage of field winding from one end of the field winding 114 at which the insulation failure has occurred.

In one example implementation, the monitoring module 220 includes a high precision resistor of a known value connected between the field terminal 116A or 116B and ground. The monitoring module 220 measures the voltage drop across the high precision resistor to monitor the field to ground voltage.

The spectrum analyzer 230 then identifies spectral features from the measured field to ground voltage. The spectrum analyzer 230 may identify the resonance frequency, the frequency corresponding to zero phase difference between the field to ground current and the field to ground voltage, or both.

In one implementation, the spectrum analyzer 230 may include a Fourier transform module, for example, a Fast Fourier Transform module, to compute a voltage spectral signature based on the measured field to ground voltage. The spectral signature includes the frequency content of the measured field to ground voltage, plotted against voltage amplitude of the various frequencies. The spectrum analyzer 230 may then use, for example, curve fitting algorithms, or peak detection algorithms, to identify peaks of voltage amplitude in the voltage spectral signature.

The spectrum analyzer 230 may have stored thereon, the healthy state resonance frequencies of the field winding 114. As described earlier, the healthy state resonance frequencies may be identified by mathematical analysis, simulations, or broadband sweep frequency analysis.

Apart from the voltage spectral signature, the spectrum analyzer 230 may also compute a phase plot of the phase difference between the field to ground voltage and the field to ground current. The spectrum analyzer 230 may then identify a frequency corresponding to zero phase difference between the field to ground voltage and the field to ground current. Typically, for a synchronous machine 110 with a healthy field winding 114, the frequency corresponding to zero phase difference is the same as the resonant frequency of the field winding 114. However, with degradation of the field winding insulation and an impending ground fault condition, the resonant frequency deviates from the frequency corresponding to zero phase difference. Such deviation may also be employed in determining the winding health indicator.

The prognostic module 240 then compares the identified resonant frequency with the healthy state resonant frequency of the field winding 114. The prognostic module 240 may have stored thereon, the healthy state resonant frequency of the field winding 114 of the synchronous machine 110. As discussed earlier, the healthy state resonance frequency may be identified from mathematical analysis, or simulations or baseline experiments. Alternatively, the healthy state resonance frequency may be identified by the monitoring system 140 while the synchronous machine 110 is still new. The prognostic module 240 then generates a winding health indicator based on the difference in the identified resonant frequency and the healthy state resonant frequency for the field winding 114.

In one implementation, the prognostic module 240 may compare the resonant frequency with the frequency corresponding to zero phase difference between the field to ground injected voltage and field to ground current. Such deviation may be noticed due to change in insulation resistance and capacitance. For example, the insulation resistance may be very high and thus the effect of the insulation resistance on the resonant frequency is minimal. In effect, the resonant frequency is determined by the winding inductance and insulation capacitance. The frequency corresponding to zero phase difference is very close to the resonant frequency. As the insulation degrades, the insulation resistance decreases and the frequency corresponding to zero phase difference deviates from the resonant frequency. Thus, the difference between the two frequencies may be utilized as an indicator of winding insulation health. If the difference in the two frequencies exceeds a predetermined threshold, the prognostic module 240 may raise an alarm.

Changes in resonant frequency of the field winding 114 typically represent damage to the field winding insulation, such as insulation deterioration, or complete insulation failure. The winding health indicator may be as simple as an audible alarm tone, or an alarm lamp. Alternatively, the winding health indicator may be the change in resonant frequency of the field winding 114. It is to be understood that the winding health indicator generated by the prognostic module 240 may be viewed at a location remote from the synchronous machine 110. The prognostic module 240 of the monitoring system 140 may be coupled with an output device (not shown), for example, by means of wireless communication, in order to transmit the winding health indicator data generated by the prognostic module 240. Further, the winding health indicator may be categorized in different levels based on the deviation value of identified resonance frequency and the healthy state resonance frequency. For example, in case of very high deviation values, the winding health indicator may be represented with a red light and audible alarm. This may be an indication that the field winding 114 may have undergone substantial insulation damage for which the field winding 114 may need immediate inspection.

In one example implementation, the various functions of the spectrum analyzer 230 and the prognostic module 240 are implemented as software instructions capable of being executed on a processor. In such an implementation, the software instructions may be stored on a non-transitory computer readable medium such as, but not limited to, hard disc drives, solid state memory devices, random access memory (RAM) linked with the processor, and so forth. The processor may be, for example, a general purpose microprocessor, a microcontroller, a programmable logic device, and so forth. An example computer system including such an implementation of the processor, may also include peripheral input devices such as a keyboard and a pointing device, peripheral output devices such as a visual display unit, and one or more network interfaces such as a Bluetooth adaptor, an IEEE 802.11 interface, an IEEE 802.3 Ethernet adaptor, and so forth. Alternatively, the processor may be implemented as a special purpose processor including the various modules hard-coded into the special purpose processor. Components of the computer system may be linked by one or more system busses. It should be appreciated that computer system described herein is illustrative and non-limiting. Other implementations of the computer system are within the scope of the present disclosure.

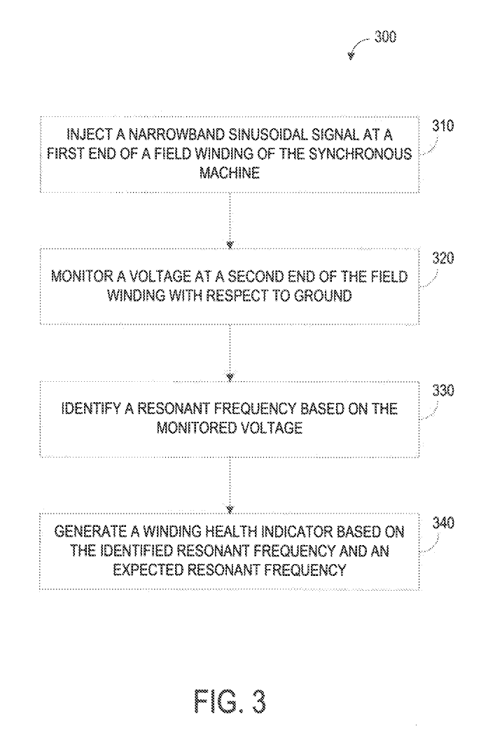

FIG. 3 is a flowchart 300 of an example method for monitoring a synchronous machine, according to one embodiment. At step 310, the signal generator 210 injects a narrowband sinusoidal signal at a field terminal 116A or 116B of a field winding 114. The narrowband sinusoidal signal may be a sinusoidal frequency sweep, or sinusoidal chirp signal. In one implementation, the narrowband sinusoidal frequency sweep signal has a frequency band that includes the healthy state resonant frequency of the field winding 114, and at least one harmonic of the healthy state resonant frequency.

At step 320, the monitoring module 220 monitors the voltage at the opposite field terminal 116A or 116B with respect to ground. For instance, if the signal generator 210 injects the narrowband sinusoidal signal at field terminal 116A, the monitoring module 220 monitors the field to ground voltage at field terminal 116B, and vice versa.

At step 330, the spectrum analyzer 230 identifies the resonant frequency of the field winding 114 based on the monitored field to ground voltage. The spectrum analyzer 230 may compute a Fourier transform of the monitored field to ground voltage to generate a voltage spectral signature, and use peak fitting algorithms to identify the resonant frequency as the peak of the voltage spectral signature.

At step 340, the prognostic module 240 may then compute a difference between the identified resonant frequency, and the healthy state resonant frequency. The prognostic module 240 may then generate a winding health indicator based on the computed difference.

1. A method for monitoring a synchronous machine comprising:
injecting a narrowband sinusoidal signal at a first end of a field winding of the synchronous machine;
monitoring a voltage at a second end of the field winding with respect to ground;
identifying a resonant frequency based on the monitored voltage; and
generating a winding health indicator based on the identified resonant frequency and an expected resonant frequency.

2. The method of claim 1, wherein the narrowband sinusoidal signal comprises a narrowband chirp signal.

3. The method of claim 1, wherein the narrowband sinusoidal signal comprises a resonant frequency sinusoid.

4. The method of claim 1 further comprising:
injecting the sinusoidal chirp signal at the second end of the field winding;
monitoring a second voltage at the first end of the field winding with respect to ground;
computing a first spectral signature based on the voltage;
computing a second spectral signature based on the second voltage; and
generating a fault location indicator based on the first spectral signature and the second spectral signature.

5. The method of claim 1 further comprising:
identifying a frequency corresponding to zero phase difference between winding to ground current, and winding to ground injected voltage;
computing a difference between the identified frequency and the resonant frequency; and
generating the winding health indicator based on the difference.

6. A system for monitoring a synchronous machine comprising:
a signal generator for injecting a narrowband sinusoidal signal at a first end of the field winding of the synchronous machine;
a monitoring module for monitoring at a second end of the field winding, a voltage with respect to ground;
a spectrum analyzer for identifying a resonant frequency based on the monitored voltage; and
a prognostic module for generating a winding health indicator based, at least in part, on the identified resonant frequency.

7. The system of claim 6, wherein the narrowband sinusoidal signal comprises a narrowband sinusoidal chirp signal.

8. The system of claim 6, wherein the narrowband sinusoidal signal comprises a resonant frequency sinusoid.

9. The system of claim 6 wherein:
the signal generator is further configured to inject the sinusoidal chirp signal at the second end of the field winding;
the monitoring module is further configured to monitor a second voltage at the first end of the field winding with respect to ground;
the spectrum analyzer is further configured to compute a first spectral signature based on the voltage, and compute a second spectral signature based on the second voltage; and
the prognostic module is further configured to generate a fault location indicator based on the first spectral signature and the second spectral signature.

10. The system of claim 6, wherein:
the spectrum analyzer is further configured to identify a frequency corresponding to zero phase difference between winding to ground current, and winding to ground injected voltage; and
the prognostic module is further configured to generate the winding health indicator based on a difference between the identified frequency and the resonant frequency.
